(19) United States
(12) Patent Application Publication
(10) Pub. No.: US 2010/0035410 A1
(43) Pub. Date: Feb. 11, 2010

(54) Method for Manufacturing InGaN

(75) Inventors: Masayuki Sonobe, Kyoto-fu (JP); Norikazu Ito, Kyoto-fu (JP); Kazuaki Tsutsumi, Kyoto-fu (JP); Tetsuya Fujiwara, Kyoto-fu (JP); Shinichi Tamai, Kyoto-fu (JP)

Correspondence Address: RABIN & Berdo, PC, 1101 14TH STREET, NW, SUITE 500, WASHINGTON, DC, 20005, US

(73) Assignee: Rohm Co., Ltd, Kyoto-fu (JP)

(21) Appl. No.: 12/086,418

(22) PCT Filed: Dec. 7, 2006
(86) PCT No.: PCT/JP2006/324438

§ 371 Date: Sep. 29, 2009

(30) Foreign Application Priority Data
Dec. 13, 2005 (JP) 2005 359219

(51) Int. Cl. H01L 21/20

(52) U.S. Cl. 438/478; 257/E21.09

(57) ABSTRACT

To provide a method for manufacturing InGaN which causes less segregation of In and achieves high crystallinity of an InGaN layer with the proportion of In increased.

The method for manufacturing an InGaN layer including growing an InGaN layer under conditions of a growth temperature of 700 to 790° C., a growth rate of 30 to 93 Å/min, and a flow rate of trimethylindium of 0.882×10⁻⁵ to 3.53×10⁻⁵ mol/min.

### TECHNICAL FIELD

The present invention relates to a method for manufacturing InGaN for making semiconductor laser or the like.

### BACKGROUND ART

As light source of optical information recording systems such as next-generation DVDs, semiconductor light emitting devices each including an active layer having an InGaN layer which can emit light in a violet-blue range and to which information can be written with high density have attracted attention.

Generally, to manufacture a semiconductor light emitting device including an InGaN layer, an n-GaN layer is formed on a substrate, and the InGaN layer is then formed on the n-GaN layer. There are known various methods for manufacturing the InGaN layer. For example, one of the known manufacturing methods is a method by a reaction rate controlling mode in which the InGaN layer is formed with trimethylindium (hereinafter, referred to as TMIn) being excessively flown for purposes of increasing an amount of In incorporated in the InGaN layer. In this reaction rate controlling mode, the InGaN layer is grown on the surface of the n-GaN layer or the like by excessively flowing TMIn while controlling growth temperature.

However, when the InGaN layer is grown by the reaction rate controlling mode, TMIn is excessively flown, so that excess In which cannot be involved in the growth of the InGaN layer is segregated in the surface of the InGaN layer. If the InGaN layer is further grown in such a state, blocks composed of substantially only In metal are formed in the InGaN layer, thus lowering the crystallinity of the InGaN layer.

Accordingly, when the proportion of In is increased for purposes of causing the InGaN layer to emit blue to green light in particular, the InGaN layer becomes black and has low optical transparency. Moreover, if a p-GaN layer is grown on such a InGaN layer, a high resistance layer is formed, thus degrading the performance of the semiconductor light emitting device.

In order to prevent the segregation of In in the InGaN layer, therefore, another manufacturing method based on a flow rate controlling mode is performed, in which the InGaN layer is grown at a flow rate of TMIn less than that of the reaction rate controlling mode. In this flow rate controlling mode, the InGaN layer is grown by adjusting the flow rate of TMIn according to the growth temperature of the InGaN layer.

### Patent Literature 1: Japanese Patent Laid-open Publication No. 6-209122

### DISCLOSURE OF THE INVENTION

### Problems to be Solved by the Invention

If the InGaN layer is grown by the flow rate controlling mode, in which the flow rate of TMIn is considerably lower than that of the reaction rate controlling mode, the segregation of In can be prevented, but the proportion of In in the InGaN layer is reduced. Herein, to increase the proportion of the In in the InGaN layer, the growth temperature of the InGaN layer needs to be lowered. However, if the growth temperature thereof is lowered, the crystallinity of the InGaN layer is reduced.

The present invention was made to solve the aforementioned problems, and an object of the present invention is to provide a method for manufacturing InGaN which causes little segregation of In and provides high crystallinity of an InGaN layer with a proportion of In increased.

### Technical Solution

To achieve the aforementioned object, an invention according to claim 1 is a method for manufacturing an InGaN characterized by growing the InGaN layer under conditions of a growth temperature of 700 to 790° C., a growth rate of 30 to 93 Å/min, and a flow rate of trimethylindium of 0.882×10⁻⁵ to 3.53×10⁻⁵ mol/min. The flow rate of TMIn herein is a value for 35° C. and 900 Torr.

Furthermore, an invention according to claim 2 is the method for manufacturing an InGaN according to claim 1, in which hydrogen is not supplied at growing the InGaN layer.

### EFFECT OF THE INVENTION

According to the present invention, crystalline growth of the InGaN layer is performed at a flow rate of trimethylindium of 0.882×10⁻⁵ to 3.53×10⁻⁵ mol/min. This can reduce segregation of In and increase the proportion of In in the InGaN layer. Accordingly, the growth temperature of the InGaN layer can be increased, so that the crystallinity of the InGaN layer can be improved.

### BRIEF DESCRIPTION OF THE DRAWINGS

FIG. 1 is a graph showing a relation between time and temperature at growing a semiconductor light emitting device.

FIG. 2 is a view showing a cross-sectional structure of the semiconductor light emitting device manufactured by a method for manufacturing an InGaN layer according to the present invention.

FIG. 3 is a schematic view showing the whole of a growth apparatus for growing the semiconductor light emitting device.

FIG. 4 is a fluorescence micrograph of an InGaN layer manufactured by the method for manufacturing an InGaN layer according to the present invention.

FIG. 5 is a fluorescence micrograph of an InGaN layer manufactured by a manufacturing method different from the manufacturing method of the present invention.

FIG. 6 is a graph showing a relation between a flow rate of TMIn and a proportion of In in an InGaN layer.

FIG. 7 is a graph showing a relation between the flow rate of TMIn and the proportion of In in an InGaN layer when the InGaN layer is grown without a supply of H₂.

### EXPLANATION OF REFERENCE NUMERALS

1. SAPPHIRE SUBSTRATE
2. n-Type Buffer Layer
3. n-GaN LAYER
4. InGaN ACTIVE LAYER
5. p-AlGaN LAYER
6. p-GaN LAYER
11. GROWTH CHAMBER
12. LOAD LOCK CHAMBER
13. VALVE
14. SUBSTRATE HOLDER
15. CONVEYING BAR

### BEST MODE FOR CARRYING OUT THE INVENTION

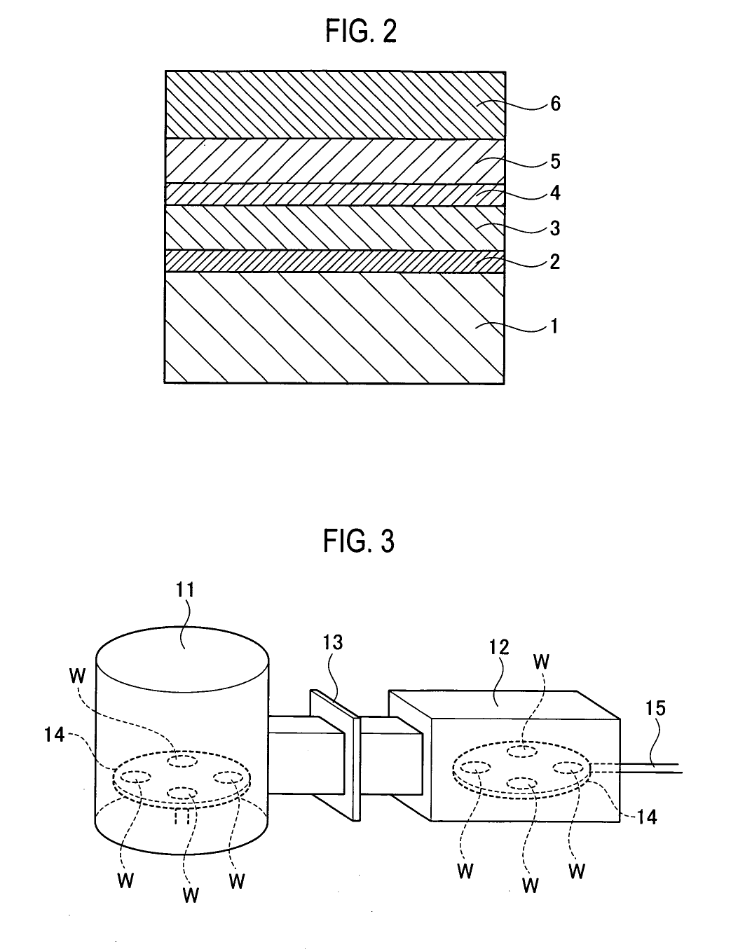

Hereinafter, a description is given of an embodiment of the present invention with reference to the drawings. FIG. 2 is a view showing a cross-sectional structure of a semiconductor light emitting device including an InGaN layer according to the present invention.

As shown in FIG. 2, the semiconductor light emitting device including the InGaN layer manufactured by a manufacturing method of the present invention includes a sapphire substrate 1, an n-type buffer layer 2, an n-GaN layer 3, an InGaN active layer 4, a p-AlGaN layer 5, and a p-GaN layer 6, which are stacked on each other.

FIG. 3 is a schematic view of a manufacturing apparatus for manufacturing the above semiconductor light emitting device. The manufacturing apparatus includes a growth chamber 11, a load lock chamber 12, and a valve 13 dividing the growth chamber 11 and load lock chamber 12.

The growth chamber 11 is always evacuated and is not set to atmospheric pressure. The load lock chamber 12 is set to atmospheric pressure when the substrate W is introduced. Moreover, the load lock chamber 12 is set to a vacuum, which is the same as the growth chamber 11, when the introduced substrate W and substrate holder 14 are sent to the growth chamber 11 together.

After the load lock chamber 12 is evacuated, the valve 13 is opened, and the substrate W placed on the substrate holder 14 is then conveyed from the load lock chamber 12 to the growth chamber 11 by the conveying bar 15. After the valve 13 is closed, each layer is formed on the substrate W conveyed to the growth chamber 11.

When all the manufacturing process in the growth chamber 11 is finished, the load lock chamber 12 is evacuated, and the valve 13 is then closed. Thereafter, the substrate W and substrate holder 14 are conveyed to the load lock chamber 12. After the load lock chamber 12 is released to atmospheric pressure, the substrate W is taken out.

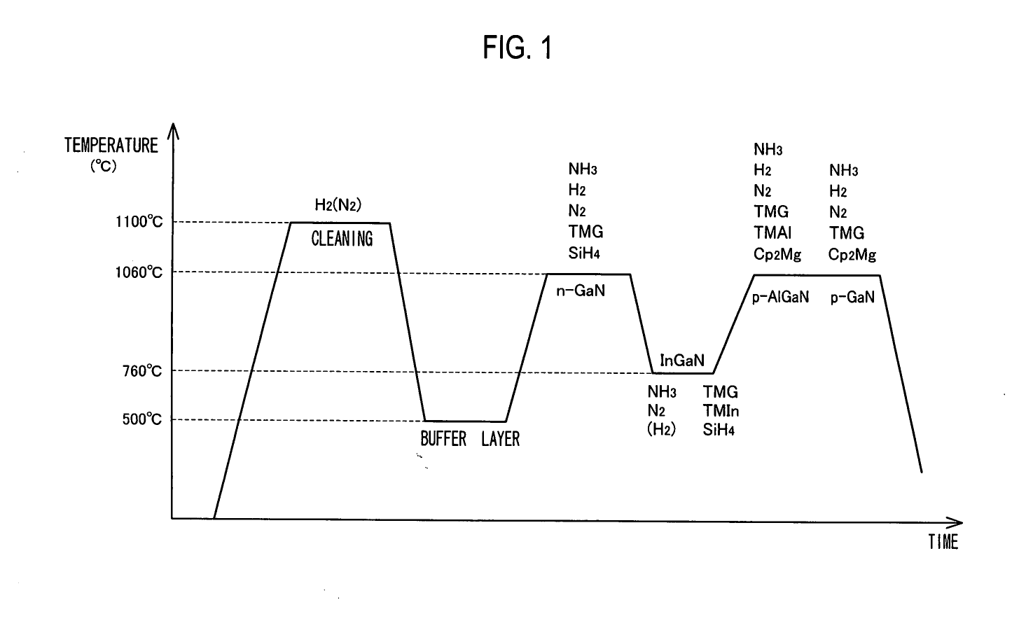

Next, a description is given of a method for manufacturing a semiconductor light emitting device including an InGaN layer according to the present invention. FIG. 1 is a diagram showing a relation between time and temperature at manufacturing the semiconductor light emitting device.

First, in a state where the sapphire substrate 1 is conveyed to the growth chamber 11, the growth chamber 11 is evacuated. As shown in FIG. 1, after the growth temperature is set to about 1100° C., H₂ and a small amount of N₂ are supplied to the growth chamber 11 for cleaning of the sapphire substrate 1. After the cleaning is finished, next, the growth temperature is reduced to about 500° C., and the n-type buffer layer 2 is then grown on the sapphire substrate 1.

Next, after the growth temperature is increased to about 1060° C., a gas mixture of NH₃, H₂, N₂, and trimethylgallium (hereinafter, referred to as TMG) is supplied to the growth chamber 11 for growth of the n-GaN layer 3. When the n-GaN layer 3 is grown, SiH₄ is simultaneously supplied to the growth chamber 11 for doping with Si, which converts the n-GaN layer 3 into n-type.

Next, the growth temperature is reduced to about 700 to 790° C., and the pressure of the growth chamber 11 is set to 200 torr. In this state, a mixture gas of NH₃, H₂, N₂, TMIn, triethylgallium (hereinafter, referred to as TEG), and SiH₄ is supplied to the growth chamber 11 for growth of the InGaN active layer 4.

Specifically, solid TMIn is prepared in a babbler, and the pressure within the bubbler is set to 900 torr. Next, N₂ as a carrier gas is flown to the babbler at a flow rate of about 0.143 mol/min to supply the gas mixture of TMIn and N₂ to the growth chamber 11. TMIn is thus supplied to the growth chamber 11 at a flow rate of about 0.882×10⁻⁵ to about 3.53×10⁻⁵ mol/min. The flow rate of TMIn herein is a value for 35° C. and 900 Torr.

The flow rate of TEG is set to about 1.88×10⁻⁵ to about 5.02×10⁻⁵ mol/min; the flow rate of NH₃, about 0.670×10⁻⁵ mol/min; the flow rate of H₂, about 4.46×10⁻³ mol/min; and the flow rate of N₂, about 0.223 mol/min. Each gas is supplied to the growth chamber 11.

For growing the InGaN active layer 4, SiH₄ is supplied at a flow rate of about 2.23×10⁻¹⁰ mol/min for doping with Si, which converts the InGaN active layer 4 into n type.

Based on these conditions, the InGaN active layer 4 is grown at a growth rate of about 30 to about 93 Å/min. At growing the InGaN active layer 4, H₂ does not need to be flown.

Next, the growth temperature is increased to 1060° C., NH₃, H₂, N₂, TMG, and TMAl are supplied for growth of the p-AlGaN layer 5. Next, with the same growth temperature being maintained, NH₃, H₂, N₂, and TMG are supplied for growth of the p-GaN layer 6. At growing the p-AlGaN layer 5 and p-GaN layer 6, cyclopentadienylmagnesium (Cp₂Mg) is also supplied to the growth chamber 11 for doping with Mg, which converts the p-AlGaN layer 5 and p-GaN layer 6 into p-type.

The semiconductor light emitting device including the InGaN active layer shown in FIG. 2 is thus completed.

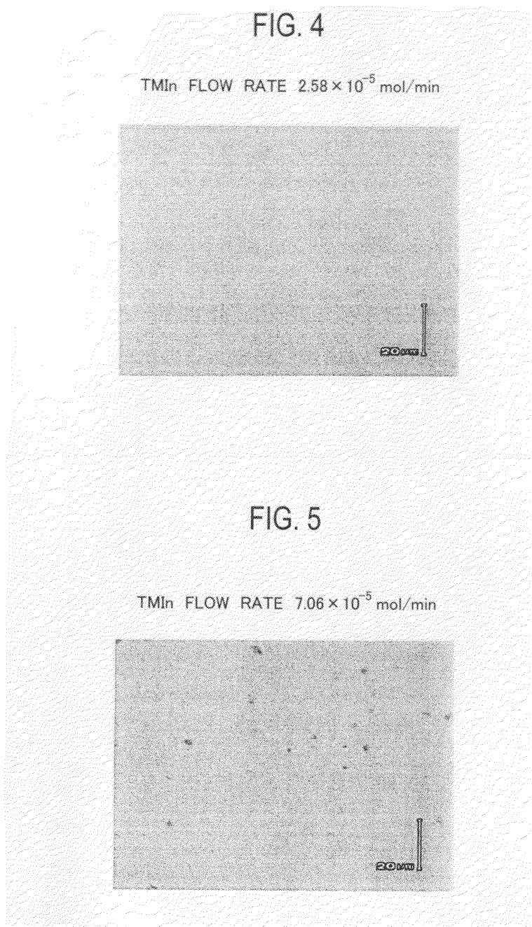

Next, with reference to FIGS. 4 and 5, a comparison is made in terms of segregation of In between the InGaN active layer manufactured based on the method for manufacturing InGaN according to the present invention and an InGaN active layer manufactured by another manufacturing method.

FIG. 4 is an image of a cross section of the InGaN active layer manufactured by the method for manufacturing InGaN of the present invention, the image being shot by a fluorescence microscope. FIG. 5 is an image of a cross section of the InGaN active layer of a comparative example manufactured by the method of the present invention with only the flow rate of TMIn changed, the image being shot by a fluorescence microscope. The InGaN active layers shown in FIGS. 4 and 5 were grown at a flow rate of TEG of about 5.02×10⁻⁵ mol/min and a growth temperature of about 780° C. without a supply of H₂.

As shown in FIG. 4, in the cross sectional structure of the InGaN active layer manufactured with the flow rate of TMIn set to about 2.58×10⁻⁵ mol/min based on the present invention, there is little segregation of In. On the other hand, as shown in FIG. 5, in the InGaN active layer grown with the flow rate (about 7.06×10⁻⁵ mol/min) of In set higher than that of the manufacturing method of the present invention, there is more In segregation (see black dots in the micrograph).

Next, a description is given of the relation between the flow rate of TMIn and growth temperature and the proportion (%) of In in the InGaN active layer by comparing samples of the InGaN active layer prepared based on the manufacturing method of the present invention and comparative samples of the InGaN active layer prepared based on another manufacturing method.

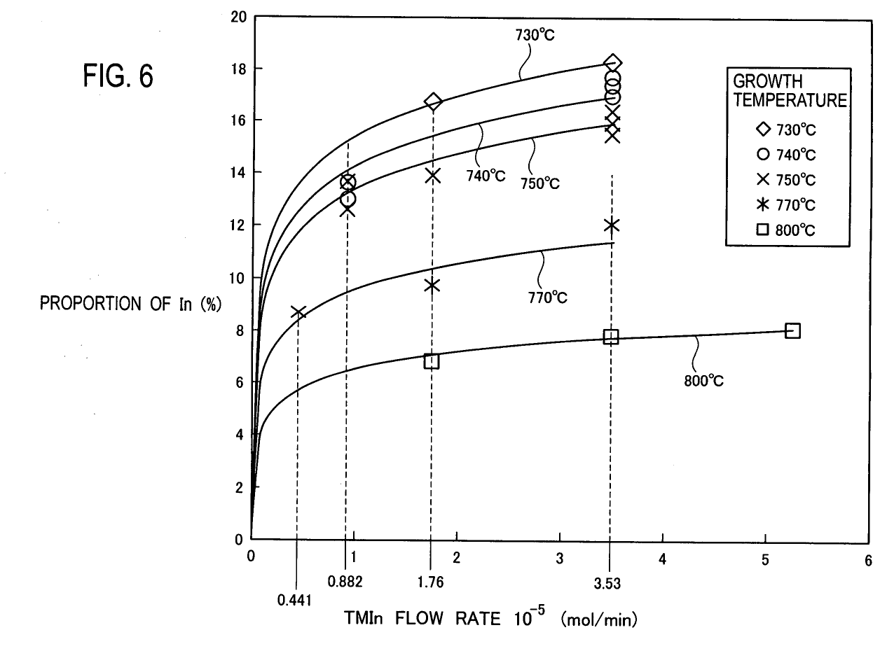

FIG. 6 shows a relation between the flow rate of TMIn and the proportion of In in the InGaN active layer for each growth temperature of the InGaN active layer (730, 740, 750, 770, and 800° C.). The flow rate of TMIn herein is a value for 35° C. and 900 Torr.

First, a description is given of the growth temperature and proportion of In. As shown in FIG. 6, when the flow rate of TMIn was adjusted based on the manufacturing method of the present invention and the growth temperature was set to about 730 to 770° C. based on the same, the proportion of In in the InGaN active layer could be about 9.8% or more. On the other hand, when the growth temperature was set to about 800° C. unlike the manufacturing method of the present invention, the proportion of In in the InGaN active layer was as low as about 8.2% even if the flow rate of TMIn was increased.

Next, a description is given of the flow rate of TMIn and proportion of In. As shown in FIG. 6, when the growth temperature was set based on the manufacturing method of the present invention and the flow rate of TMIn was set to about 0.882×10⁻⁵ mol/min or more based on the same, the proportion of In in the InGaN active layer could be about 9.2% or more. On the other hand, when the InGaN active layer was grown with the flow rate of In set to about 0.441×10⁻⁵ mol/min unlike the manufacturing method of the present invention, the proportion of In in the InGaN active layer was as low as about 8.9%.

Moreover, unlike the manufacturing method of the present invention, it can be predicted from the experiment results of FIG. 6 that the proportion of In in the InGaN active layer is little increased even if the flow rate of TMIn is increased to not less than about 3.53×10⁻⁵ mol/min. Accordingly, setting the flow rate of TMIn to about 3.53×10⁻⁵ mol/min or more only increases segregation of In and has no advantage.

As described above, by setting the growth conditions of the InGaN active layer with a growth temperature of about 700 to 790° C., a growth rate of about 30 to about 93 Å/min, and a flow rate of TMIn of about 0.882×10⁻⁵ to about 3.53×10⁻⁵ mol/min, the segregation of In in the InGaN active layer can be prevented while the proportion of In in the InGaN active layer is increased. Moreover, although the proportion of In is generally reduced as the growth temperature increases, under the above growth conditions, the proportion of In can be increased, so that the temperature at growing the InGaN active layer can be increased. It is therefore possible to increase the crystallinity of the InGaN active layer which contains high proportion of In and can emit blue or green light.

Hereinabove, the present invention is described in detail using the embodiment, but it is apparent to those skilled in the art that the present invention is not limited to the embodiment explained in the specification. The present invention can be carried out as modified and changed modes without departing from the spirit and scope of the invention defined by the description of claims. Accordingly, the description of this specification is for illustrative purposes and does not impose any limitation on the present invention. A description is given below of modified modes obtained by partially changing the embodiment.

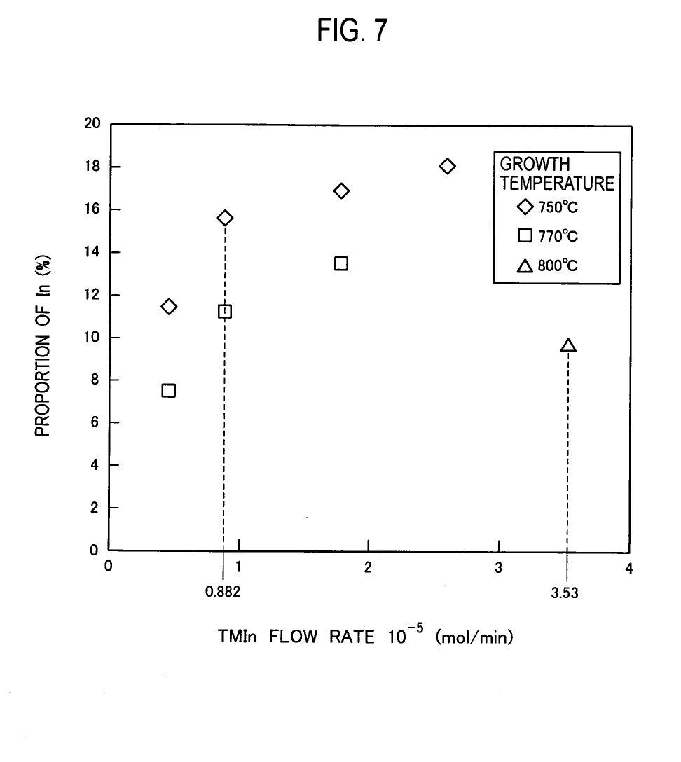

For example, the InGaN active layer may be grown without a supply of H₂ as described above. A description is given of the case of growing the InGaN active layer without a supply of H₂ with reference to FIG. 7. FIG. 7 is a graph showing a relation between the flow rate of TMIn and proportion of In when the InGaN active layer is grown without a supply of H₂.

Comparing the graphs of FIGS. 7 and 6, it is found that the proportion of In in the InGaN active layer is higher in the case of growing the InGaN active layer without a supply of H₂ when the other growth conditions are the same. For example, when the growth temperature and flow rate of TMIn were set to about 750° C. and 1.76×10⁻⁵ mol/min, respectively, the InGaN active layer grown without a supply of H₂ had a proportion of In of about 17.0% while the InGaN active layer with a supply of H₂ had a proportion of In of about 14.0%. This revealed that growing the InGaN active layer without a supply of H₂ could provide a higher proportion of In than that in the case of growing the InGaN active layer with a supply of H₂.

Moreover, the flow rate of TEG at growing the InGaN active layer can be changed. Next, a description is given of the relation between the flow rate of TEG and proportion of In in the InGaN active layer. In the following explanation, the InGaN active layer was grown at a flow rate of TMIn of about 3.53×10⁻⁵ mol/min and a growth temperature of about 760° C. without a supply of H₂

When the flow rate of TEG at forming the InGaN active layer was about 1.88×10⁻⁵ mol/min, the proportion of In in the InGaN active layer was about 17.6%. On the other hand, when the flow rate of TEG at forming the InGaN active layer was about 5.02×10⁻⁵ mol/min, the proportion of In in the InGaN active layer was increased to about 19.4%. This reveals that increasing the flow rate of TEG can increase the proportion of In in the InGaN active layer.

What is claimed is:

1. A method for manufacturing InGaN comprising:
a step of growing an InGaN layer under conditions of a growth temperature of 700 to 790° C., a growth rate of 30 to 93 Å/min, and a flow rate of trimethylindium of 0.882×10⁻⁵ to 3.53×10⁻⁵ mol/min.

2. The method of claim 1, wherein
hydrogen is not supplied at growing the InGaN layer.
